(19) United States
(12) Patent Application Publication
(10) Pub. No.: US 2015/0155290 A1
(43) Pub. Date: Jun. 4, 2015

(54) SEMICONDUCTOR DEVICE

(71) Applicant: KABUSHIKI KAISHA TOSHIBA, Minato-ku (JP)

(72) Inventors: Hideto TAKEKIDA, Nagoya (JP); Saku HASHIURA, Yokkaichi (JP)

(73) Assignee: KABUSHIKI KAISHA TOSHIBA, Minato-ku (JP)

(21) Appl. No.: 14/506,100

(22) Filed: Oct. 3, 2014

Related U.S. Application Data
(60) Provisional application No. 61/911,539, filed on Dec. 4, 2013.

(51) Int. Cl. H01L 27/115; H01L 49/02; H01L 29/49; H01L 29/788

(52) U.S. Cl. CPC H01L 27/11526; H01L 29/788; H01L 28/20; H01L 29/4916; H01L 27/11521

(57) ABSTRACT

A semiconductor device including a memory cell region including a memory cell in which a floating electrode is disposed above a gate insulating film and a control electrode is stacked above the floating electrode via an interelectrode insulating film, wherein the floating electrode of the memory cell includes a first polysilicon layer containing nitrogen and a second polysilicon layer containing a P-type impurity, and wherein a height of an upper surface of an end of the first polysilicon layer is higher than a height of an upper surface of an element isolation insulating film disposed in the memory cell region.

### CROSS-REFERENCE TO RELATED APPLICATION(S)

This application is based upon and claims the benefit of priority from U.S. Provisional Patent Application No. 61/911,539, filed on, Dec. 4, 2013 the entire contents of which are incorporated herein by reference.

### FIELD

Embodiments disclosed herein generally relate to a semiconductor storage device.

### BACKGROUND

In NAND flash memory devices, a P conductivity-type polysilicon layer may be used in a floating gate electrode formed above a P-type semiconductor substrate. However, when the floating gate electrode includes a P-type polysilicon layer, boron introduced as a dopant into the P-type polysilicon layer may diffuse out of the P-type polysilicon layer during the processing of the memory cell. As a result, the interface portion with the interpoly insulating film at the upper portion of the floating gate electrode may become depleted during the programming operation and cause programming errors.

### BRIEF DESCRIPTION OF THE DRAWINGS

FIG. 1 is one schematic example illustrating an electrical configuration of a semiconductor device of a first embodiment.

FIG. 2 is one example of a planar layout of the entire layout.

FIG. 3 is one schematic example of a plan view of a memory-cell region in part.

FIG. 4 is one schematic example of a plan view of a peripheral-circuit region in part.

FIG. 5 is one example of a vertical cross sectional view schematically illustrating the main portion of the semiconductor device (FIG. 5A is one example of a vertical cross sectional view schematically illustrating the cross section taken along line A-A of FIG. 3, FIG. 5B is one example of a vertical cross sectional view schematically illustrating the cross section taken along line B-B of FIG. 4, and FIG. 5C is one example of a vertical cross sectional view schematically illustrating the cross section taken along line C-C of FIG. 4).

FIGS. 6A to 6C are examples of vertical cross sectional views each schematically illustrating one phase of the manufacturing process flow of a portion corresponding to FIGS. 5A to 5C respectively.

FIGS. 7A to 7C are examples of vertical cross sectional views each schematically illustrating one phase of the manufacturing process flow of a portion corresponding to FIGS. 5A to 5C respectively.

FIGS. 8A to 8C are examples of vertical cross sectional views each schematically illustrating one phase of the manufacturing process flow of a portion corresponding to FIGS. 5A to 5C respectively.

FIGS. 9A to 9C are examples of vertical cross sectional views each schematically illustrating one phase of the manufacturing process flow of a portion corresponding to FIGS. 5A to 5C respectively.

FIGS. 10A to 10C are examples of vertical cross sectional views each schematically illustrating one phase of the manufacturing process flow of a portion corresponding to FIGS. 5A to 5C respectively.

FIGS. 11A to 11C are examples of vertical cross sectional views each schematically illustrating one phase of the manufacturing process flow of a portion corresponding to FIGS. 5A to 5C respectively.

FIGS. 12A to 12C are examples of vertical cross sectional views each schematically illustrating one phase of the manufacturing process flow of a portion corresponding to FIGS. 5A to 5C respectively.

FIGS. 13A to 13C illustrate a second embodiment and are examples of vertical cross sectional views each schematically illustrating one phase of the manufacturing process flow of a portion corresponding to FIGS. 5A to 5C respectively.

FIGS. 14A to 14C are examples of vertical cross sectional views each schematically illustrating one phase of the manufacturing process flow of a portion corresponding to FIGS. 13A to 13C respectively.

FIGS. 15A to 15C are examples of vertical cross sectional views each schematically illustrating one phase of the manufacturing process flow of a portion corresponding to FIGS. 13A to 13C respectively.

FIGS. 16A to 160 are examples of vertical cross sectional views each schematically illustrating one phase of the manufacturing process flow of a portion corresponding to FIGS. 13A to 13C respectively.

FIGS. 17A to 17C are examples of vertical cross sectional views each schematically illustrating one phase of the manufacturing process flow of a portion corresponding to FIGS. 13A to 13C respectively.

FIGS. 18A to 18C are examples of vertical cross sectional views each schematically illustrating one phase of the manufacturing process flow of a portion corresponding to FIGS. 13A to 13C respectively.

FIG. 19 illustrates a third embodiment and is one example of a plan view schematically illustrating a resistive element.

FIGS. 20A and 20B are examples of vertical cross sectional views each schematically illustrating a portion corresponding to FIGS. 5A and 5B respectively.

FIG. 20C is one example of a vertical cross sectional view schematically illustrating the cross section taken along line E-E of FIG. 19

FIGS. 21A, 21B, and 21C illustrate a fourth embodiment and correspond to FIGS. 20A, 20B, and 20C.

FIG. 22 illustrates a fifth embodiment and corresponds to FIG. 5A.

FIG. 23 is one example of a vertical cross sectional view schematically illustrating one phase of the manufacturing process flow of a portion corresponding to FIG. 22.

FIG. 24 is one example of a vertical cross sectional view schematically illustrating one phase of the manufacturing process flow of a portion corresponding to FIG. 22.

FIG. 25 is one example of a vertical cross sectional view schematically illustrating one phase of the manufacturing process flow of a portion corresponding to FIG. 22.

FIG. 26 is one example of a vertical cross sectional view schematically illustrating one phase of the manufacturing process flow of a portion corresponding to FIG. 22 and

FIG. 27 is one example of a vertical cross sectional view schematically illustrating one phase of the manufacturing process flow of a portion corresponding to FIG. 22.

### DETAILED DESCRIPTION

A semiconductor device including a memory cell region including a memory cell in which a floating electrode is disposed above a gate insulating film and a control electrode is stacked above the floating electrode via an interelectrode insulating film, wherein the floating electrode of the memory cell includes a first polysilicon layer containing nitrogen and a second polysilicon layer containing a P-type impurity, and wherein a height of an upper surface of an end of the first polysilicon layer is higher than a height of an upper surface of an element isolation insulating film disposed in the memory cell region.

Embodiments are described hereinafter with reference to the accompanying drawings. Elements substantially identical across the embodiments are identified with identical reference symbols and are not re-described. The drawings are merely schematic and not drawn to scale and thus, do not reflect the actual measurements of the features such as the correlation of thickness to planar dimensions and the relative thickness of different layers.

### First Embodiment

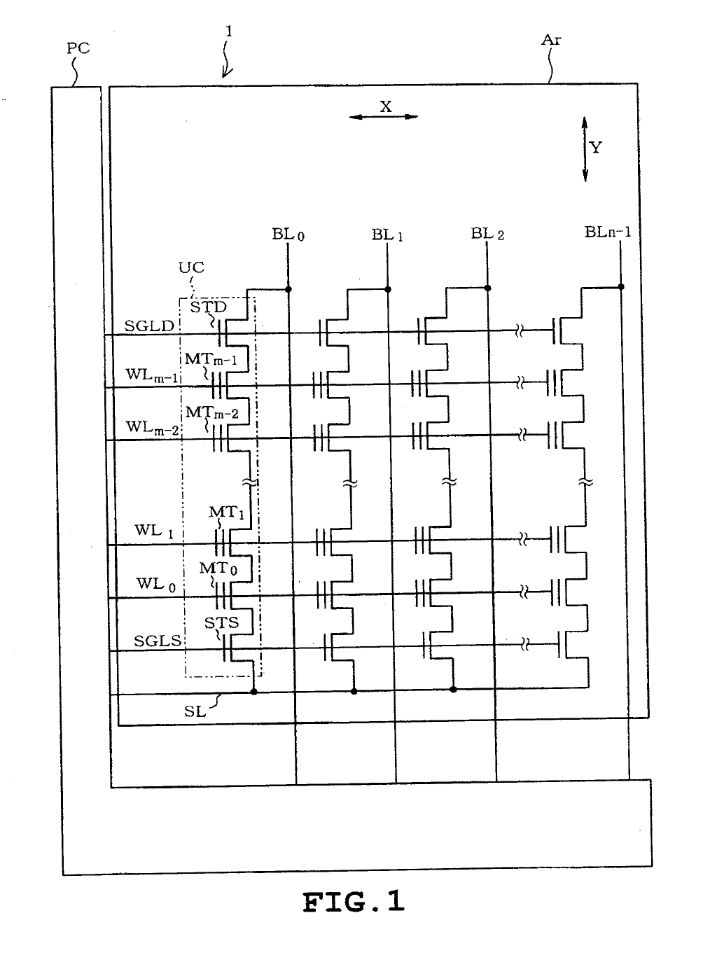

FIG. 1 schematically illustrate an electrical configuration of NAND flash memory device in a block diagram. As shown in FIG. 1, NAND flash memory device includes memory-cell array Ar and peripheral-circuit region PC that executes reading/programming/erasing of each memory cell in memory-cell array Ar.

Memory-cell array Ar includes cell units UC. Cell unit UC includes bit-line-side select gate transistors STD connected to bit lines BL₀ to BLₙ₋₁ respectively, source-line-side select gate transistors STS connected to source line SL, and 2^{k} (64 for example) of memory-cell transistors MT₀ to MTₘ₋₁ (hereinafter referred to as MT: corresponding to memory cell) for example series connected between the two select gate transistors STD and STS. Dummy transistors may be provided between select gate transistor STD and memory-cell transistor MT and between select gate transistor STS and memory-cell transistor MT.

In FIG. 1, memory-cell transistors MT aligned in the X direction (word line direction) connected by common word line WL. Further, in FIG. 1, select transistors STD aligned in the X direction are connected by common select gate line SGLD. Still further, in FIG. 1, select transistors STS aligned in the X direction are connected by common select gate line SGLS. Bit line BL extending in the Y direction (bit line direction) as viewed in FIG. 1 is connected to the drain region of select transistor STD by way of bit line contact. Further, the source regions of select transistors STS for example in a single block are connected to common source line SL.

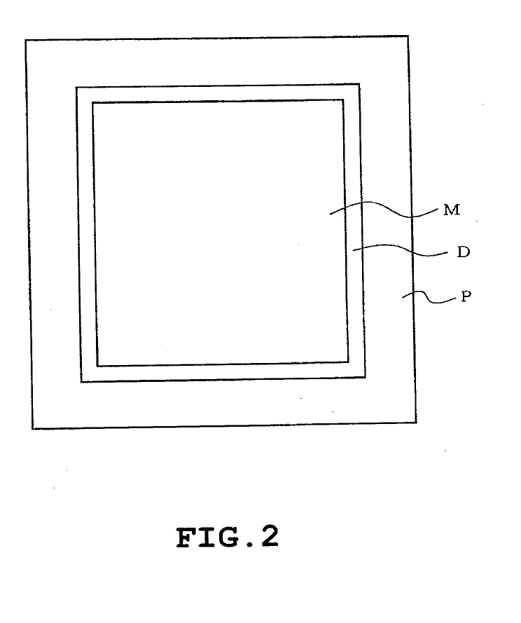

FIG. 2 illustrates one example of a planar layout of each region in the NAND flash memory. As shown in FIG. 2, memory-cell region M is provided as a rectangular (including square) region being surrounded by peripheral-circuit region P shaped like a rectangular frame. Dummy cell region D may be provided between peripheral-circuit region P and memory-cell region M. Memory cell transistors MT are disposed in memory-cell region M. Various transistors (p-channel type MOS transistor, n-channel type MOS transistor) such as a high-breakdown-voltage transistor and a low-breakdown-voltage transistor for driving memory cells MT are formed in peripheral-circuit region P. Dummy cells which are not electrically functional may be provided in dummy region D.

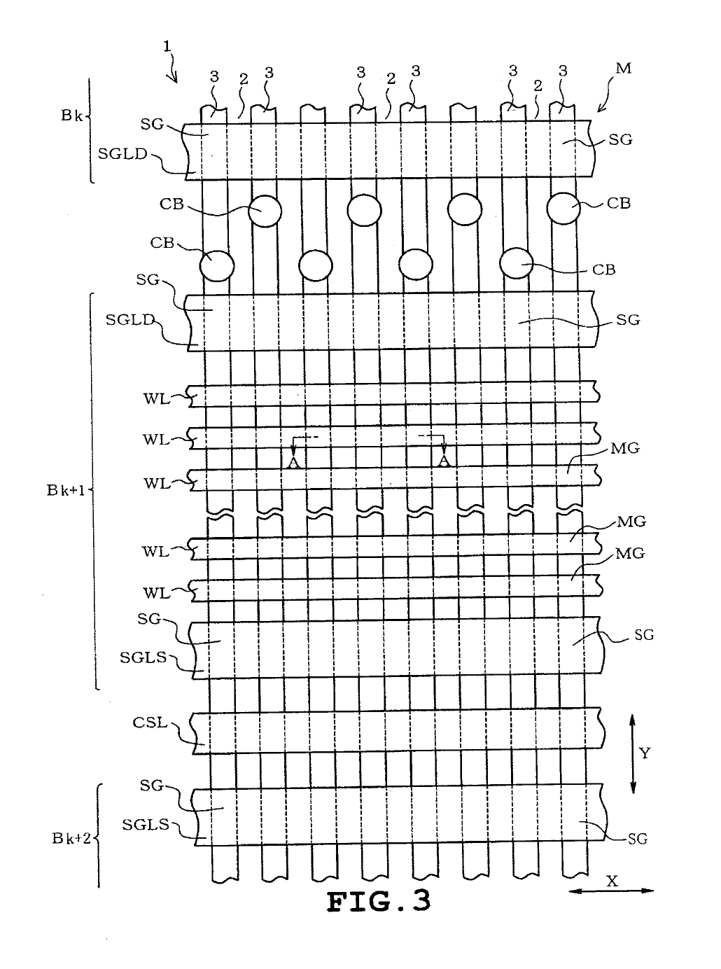

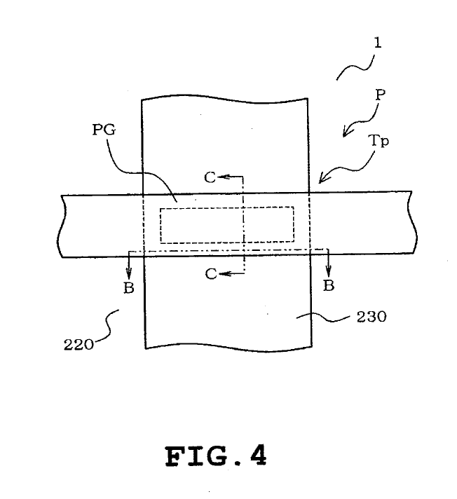

FIG. 3 partially illustrates one example of a planar layout of memory-cell region M. FIG. 4 partially illustrates one example of a planar layout of peripheral-circuit region P. In memory-cell region M, element isolation regions 2 taking an STI structure run in the Y direction of semiconductor substrate 1 as shown in FIG. 3. Element isolation regions 2 are spaced from one another in the X-direction by a predetermined spacing to form element regions 3 divided in the X direction.

Further, select gate line SGLD interconnecting select transistors STD extend along the X direction (the word line direction). A region for forming bit line contacts CB are provided between select gate lines SGLD of blocks Bₖ and Bₖ₊₁ adjacent in the Y direction (bit line direction) as viewed in FIG. 2. Bit line contact CB is formed above each element region 3 located between a pair of select gate lines SGLD. Select gate line SGLS interconnecting select transistors STS extend along the X direction. Source line contact CSL is formed above each element region 3 located between a pair of select gate lines SGLS. Source line contact CSL differs from bit line contact CB in that it is formed of a single line-shaped trench pattern extending in the word line direction.

In the plan view of memory cell region M shown in FIG. 3, gate electrode MG of memory-cell transistor MT is formed above element region 3 intersecting with word line WL. Select gate electrode SG of select transistor STD is formed above element region 3 intersecting with select gate line SGLD. Further, select gate electrode SG of select transistor STS is formed above element region 3 intersecting with select gate line SGLS.

In the plan view of peripheral-circuit region P shown in FIG. 4, element isolation regions 220 taking an STI structure are formed into semiconductor substrate 1. As a result, islands of element regions 230 are isolated from one another by element isolation regions 220. Gate electrode PG is formed so as to extend across element region 230. Transistor Tp of peripheral-circuit region P includes gate electrode PG and a drain/source region formed in the surface layer of element region 230 of semiconductor substrate 1 located beside gate electrode PG in the direction of gate length.

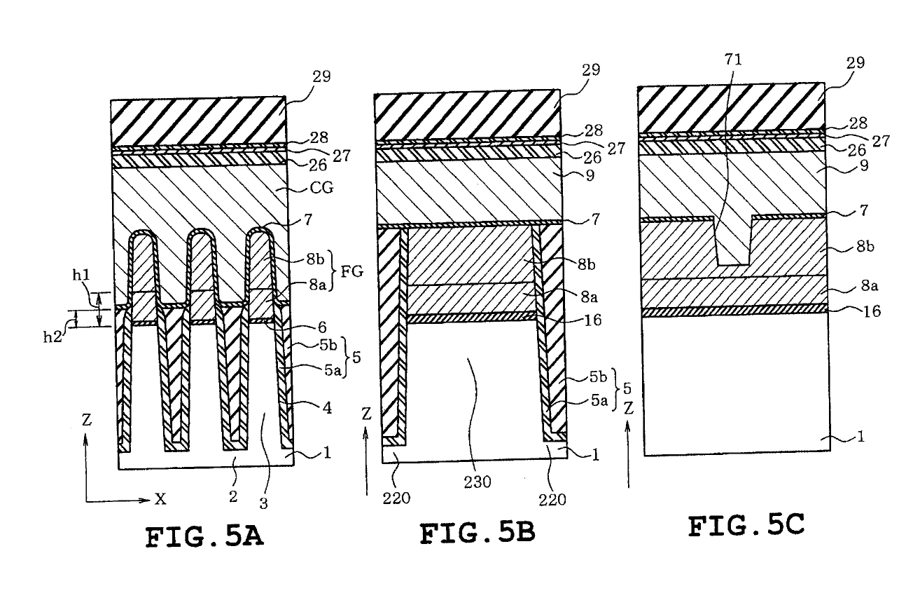

FIG. 5A is a cross sectional view taken along line A-A of FIG. 3 and schematically illustrates one manufacturing phase of the structures in memory-cell region M. As shown in FIG. 5A, element isolation trench 4 is formed into semiconductor substrate 1 which is filled with element isolation insulating film 5 to form element isolation region 2 taking an STI structure. Element isolation insulating film 5 is a double layer insulating film including a liner oxide film 5a and a silicon oxide film 5b. Element region 3 is disposed between the adjacent element isolation regions 2. Each memory-cell transistor NT is formed of a stack of gate insulating film 6, floating electrode FG, interelectrode insulating film 7, and control electrode CG disposed above element region 3.

Floating electrode FG is formed of a stack of lower polysilicon film 8a doped for example with a high concentration (approximately 1*10²¹ to 1*10²² cm⁻³ for example) of nitrogen (N) to and upper polysilicon film 8b doped with a high concentration (approximately 5*10²⁰ to 5*10²¹ cm⁻³ for example) of a P-type impurity (such as boron (B)). The sidewalls and the upper surface of upper polysilicon film 8b are covered with interelectrode insulating film 7. The upper sidewalls of lower polysilicon film 8a are covered with interelectrode insulating film 7. The lower sidewalls of lower polysilicon film 8a are covered with element isolation insulating film 5.

Height h1 (height from the under surface of gate insulating film 6) of the upper end portion of lower polysilicon film 8a as viewed in the X direction is higher than height h2 (height from the under surface of gate insulating film 6 to the upper surface of the contact interface portion of element isolation insulating film 5 and floating electrode FG) of the upper surface of element isolation insulating film 5.

Interelectrode insulating film 7 is a film disposed between floating electrode FG and control electrode CG and may also be referred to as an interpoly insulating film or an inter-conductive-layer insulating film. Interelectrode insulating film 7 is formed of for example a stack of nitride film/oxide film/nitride film/oxide film (the so called NONO film (Nitride-Oxide-Nitride-Oxide film)). Interelectrode insulating film 7 may be formed of for example: oxide film/nitride film/oxide film (the so called ONO film (Oxide-Nitride-Oxide film)) or nitride film/oxide film/nitride film/oxide film/nitride film (the so called NONON film (Nitride-Oxide-Nitride-Oxide-Nitride film)) or oxide film/nitride film/oxide film/nitride film (the so called ONON film (Oxide-Nitride-Oxide-Nitride film)). The nitride film in the mid portion of the stack may be replaced by a high-dielectric-constant film having a relative dielectric constant higher than the relative dielectric constant of the nitride film or by an oxynitride film having high oxygen content.

Control electrode CG is formed of for example polysilicon film 9 doped with p-type impurities such as boron and is formed above interelectrode insulating film 7. Control electrode CG may be formed of a structure including a polysilicon film and a low-resistance metal film formed above it, or control electrode CG may be formed entirely of a low-resistance metal film.

Memory-cell transistor MT stores data in a nonvolatile manner based on the charge storing status of floating electrode FG. More specifically, data is stored by allocating “0” data for example to a high threshold voltage state in which the electrons are injected into floating electrode FG from the channel and by allocating “1” data for example to a low threshold voltage state in which the electrons of floating electrode FG are released to the channel. Multilevel storage scheme is recently being implemented such as a binary storage in which the threshold distribution is divided into four segments or a ternary storage in which the threshold distribution is divided into eight segments by refining the control of threshold distribution.

When floating electrode FG is doped with P conductivity-type impurities, it is possible to increase the work function. When polysilicon film 8 of floating electrode FG is doped with P conductivity-type impurities, electric field concentration may occur at the interface of floating electrode FG and interelectrode insulating film 7 and cause the interface region to be depleted when a high positive voltage is applied to control electrode CG by peripheral circuit PC during the programming process. Under such circumstances, boron introduced as dopant into the P-type polysilicon layer may diffuse out (external diffusion) of polysilicon film 8 by thermal processes, or the like, carried out during memory cell processing. In such case, the depletion formed at the interface of floating electrode FG and interelectrode insulating film 7 becomes thick. As a result, a programming error may occur.

Thus, in the present embodiment, floating electrode FG is formed by stacking lower polysilicon film 8a doped with nitrogen and upper polysilicon film 8b doped with boron for example. Further, height h1 of the upper end portion of lower polysilicon film 8a is configured to be higher than height h2 of the upper surface of element isolation insulating film 5. According to such structure, it is possible to cover the under surface, the sidewalls, and the upper surface of upper polysilicon film 8b doped with high concentration of boron with lower polysilicon film 8a doped with high concentration of nitrogen and the nitride film of interelectrode insulating film 7. As a result, upper polysilicon film 8b is surrounded by nitrogen as viewed in the cross section taken along the X direction (word line direction) and thus, it is possible to inhibit diffusion of boron introduced into upper polysilicon film 8b as a dopant by a thermal process, or the like, carried out during memory cell processing. Thus, it is possible to inhibit increasing of the depletion thickness near the interface where floating electrode FG contacts interelectrode insulating film 7 and thereby inhibit programming errors.

FIG. 5B schematically illustrates the cross section (cross section taken along line B-B of FIG. 4) of a main portion of peripheral-circuit region P. FIG. 5C schematically illustrates the cross section (cross section taken along line C-C of FIG. 4) of a main portion of peripheral-circuit region P.

As show in FIGS. 5B and 5C, gate insulating film 16 having a thickness thicker than gate insulating film 6 is formed above element region 230 and lower polysilicon film 8a and upper polysilicon film 8b are stacked above gate insulating film 16. Lower polysilicon film 8a and upper polysilicon film 8b are formed when lower polysilicon film 8a and upper polysilicon film 8b constituting the aforementioned floating electrode FG are formed and are made of the similar materials.

Upper polysilicon film 8b is formed so that its upper surface is substantially level in the Z direction with the upper surface of element isolation insulating film 5 and interelectrode insulating film 7 is formed continuously along element isolation insulating film 5 and upper polysilicon film 8b. Polysilicon film 9 is formed above interelectrode insulating film 7. Polysilicon film 9 is formed when polysilicon film 9 constituting the aforementioned control electrode CG is formed with similar materials.

As shown in FIG. 5C, opening 71 is formed through interelectrode insulating film 7 and upper polysilicon film 8b. Polysilicon film 9 and upper polysilicon film 8h are connected through opening 71. The under surface of polysilicon film 9 in opening 71 is higher in elevation than the upper surface of lower polysilicon film 8a. Opening 71 is formed by for example RIE (Reactive Ion Etching) which is followed by wet etching using hydrofluoric acid for example. When the grain diameters of polysilicon of polysilicon films 8a and 8b are large, the hydrofluoric acid permeates into the polysilicon films 8a and 8b and reaches gate insulating film 16. This may degrade the properties of the gate insulating film. In contrast, in the present embodiment, it is possible to reduce the grain diameter of polysilicon of lower polysilicon film 8a because a high concentration of nitrogen is doped in lower polysilicon film 8a. As a result, it is possible to inhibit permeation of hydrofluoric acid into polysilicon film 8a during the wet etching and prevent degradation of gate insulating film 16. Further, it is possible to inhibit permeation of hydrofluoric acid into polysilicon film 8a more effectively by configuring the under surface of polysilicon film 9 to be higher than the upper surface of lower polysilicon film 8a.

Further, it is possible to form cap film 26 formed of a silicon nitride film, liner film 27 formed of a silicon oxide film, silicon nitride film 28 serving as a stopper film, and interlayer insulating film 29 one after another above polysilicon film 9 in memory-cell region 11 and peripheral circuit region P.

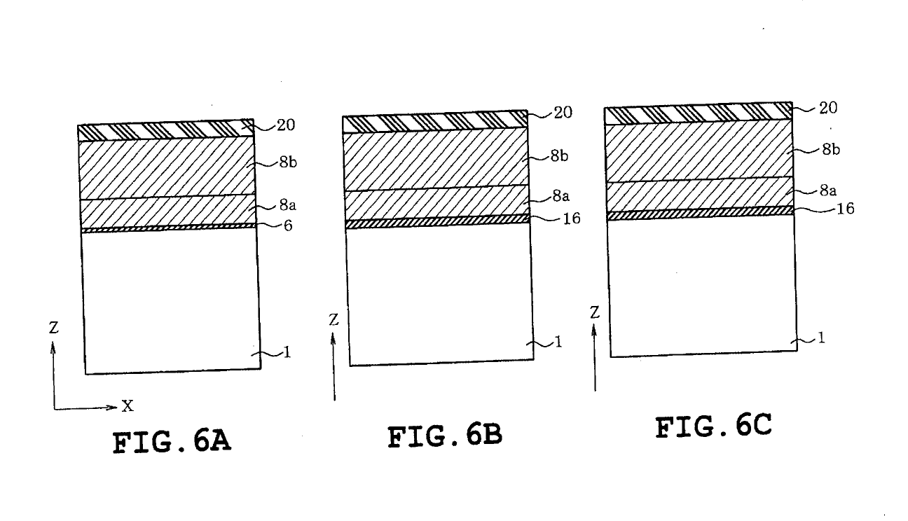

Next, description will be given on the manufacturing process flow in a step by step manner with reference to FIGS. 6A to 12C. The process steps are described below focusing on their features and known steps may be added. FIGS. 6A to 12A are cross sectional views taken along line A-A of FIG. 3 and schematically illustrate the manufacturing process flow of the structures in memory-cell region M. FIGS. 6B to 12B are cross sectional views taken along line B-B of FIG. 4 and schematically illustrate the manufacturing process flow of the structures in memory cell peripheral-circuit region P. FIGS. 6C to 12C are cross sectional views taken along line C-C of FIG. 4 and schematically illustrate the manufacturing process flow of the structures in memory cell peripheral-circuit region P.

As shown in FIGS. 6A to 6C, gate insulating films 6 and 16 are formed for example by thermal oxidation above semiconductor substrate 1 in memory-cell region M and peripheral-circuit region P. Gate insulating film 6 in memory-cell region M is formed of for example silicon oxide film and serves as a tunnel insulating film. Gate insulating film 16 having a thickness thicker than the thickness of gate insulating film 6 is formed in the region for forming a high-breakdown-voltage transistor in peripheral-circuit region P.

Then, lower polysilicon film 8a is formed above gate insulating films 6 and 16 at the same time by CVD (Chemical Vapor Deposition). Polysilicon film 8a is formed by doping a high concentration of nitrogen in the dose of for example approximately 1*10²¹ to 1*10²² cm⁻³. Next, upper polysilicon film 8b is formed at the same time above lower polysilicon film 8a by CVD. Upper polysilicon film 8b is formed by doping a high concentration of boron in the dose of for example approximately 5*10²⁰ to 5*10²¹ cm⁻³. Further, hard mask 20 made of for example a silicon nitride film or a silicon oxide film, or the like is formed above upper polysilicon film 8b.

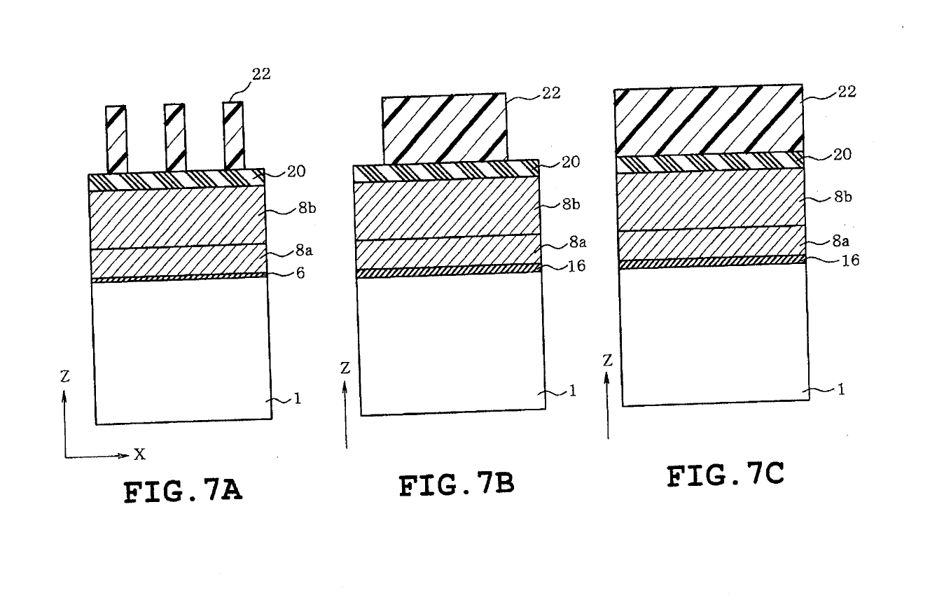

Then, as shown in FIGS. 7A to 7C, resist 22 is coated above hard mask 20 and resist 22 is patterned by lithography.

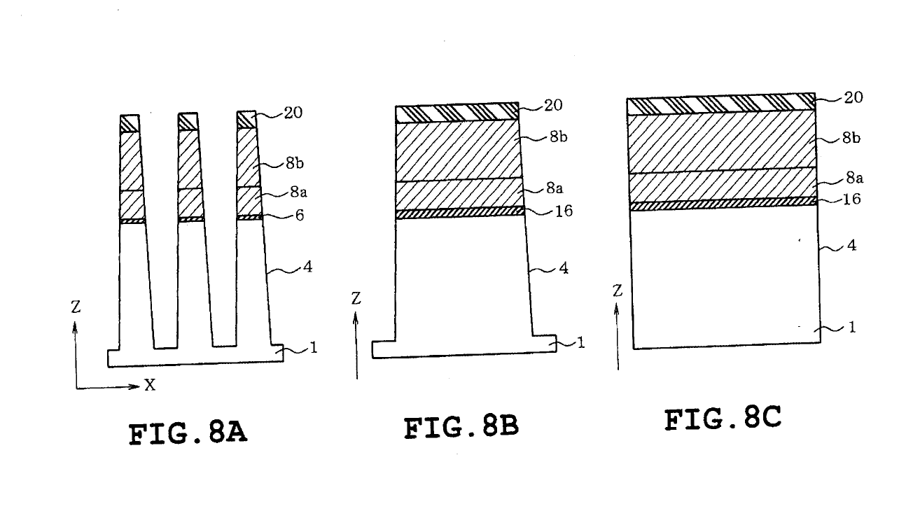

As shown in FIGS. 8A to 5C, using the patterned resist 22 as mask, element isolation trench 4 is formed by processing hard mask 20, polysilicon films 8b and 8a, gate insulating films 6 and 16, and the upper portion of semiconductor substrate 1 one after another by RIE. Element isolation insulating trench 4 may be formed in a width beyond the resolution limit (critical dimension) of lithography by using the so called sidewall transfer technique.

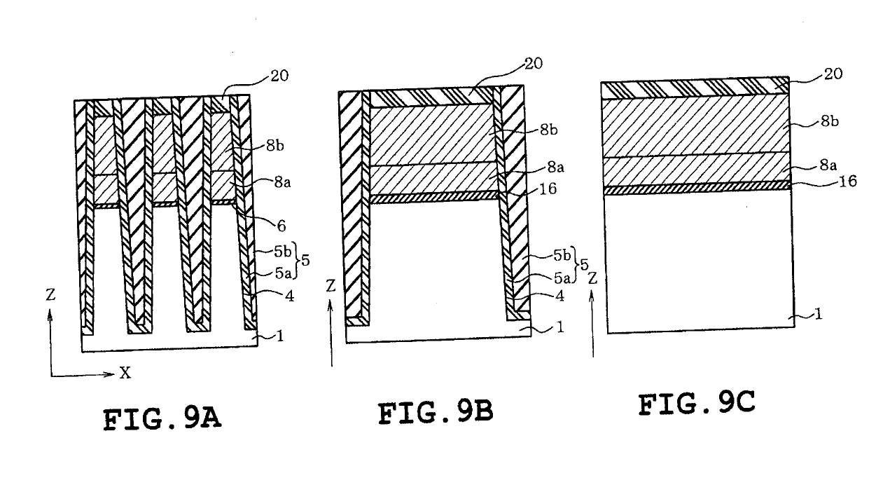

Subsequently, as shown in FIGS. 9A to 9C, liner oxide film 5a is formed along the inner surface of element isolation trench 4 by using CVD for example, whereafter a polysilazane solution is coated above liner oxide film 5a using a coating technique to coat the trench and thereafter heated. As a result, the polysilazane is converted to silicon oxide film 5b to form a double layered element isolation insulating film 5. Then, element isolation insulating film 5 is planarized by CMP for example using hard mask 20 as a stopper.

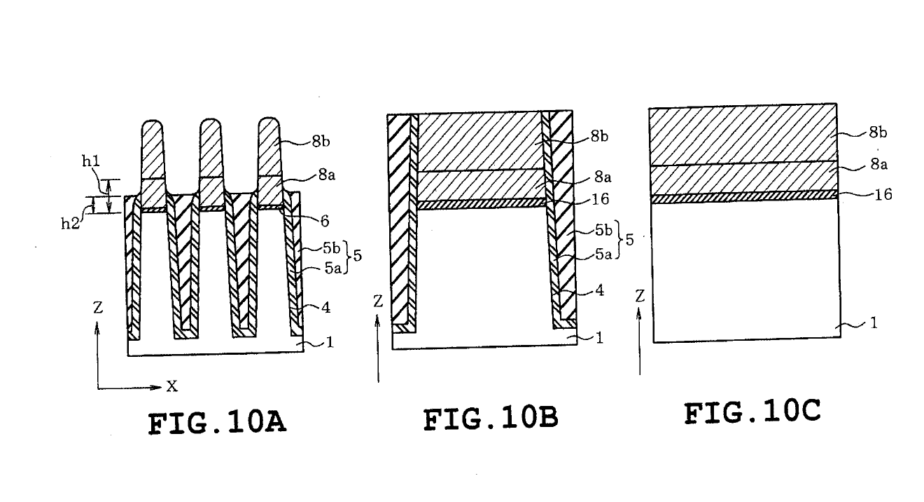

Then, as shown in FIGS. 10A to 10C, the upper portion of element isolation insulating film 5 in memory-cell region M is etched for example by RIE so that height h1 of the upper end portion of lower polysilicon film 8a is higher than the height h2 of the upper surface of element isolation insulating film 5 (see FIG. 10A). Thereafter, hard mask 20 is removed for example by hot phosphoric acid treatment.

The upper surface of element isolation insulating film 5 is not etched in peripheral-circuit region P. As a result, the upper surface of element isolation insulating film 5 and the upper surface of upper polysilicon film 8b are substantially level in peripheral-circuit region P.

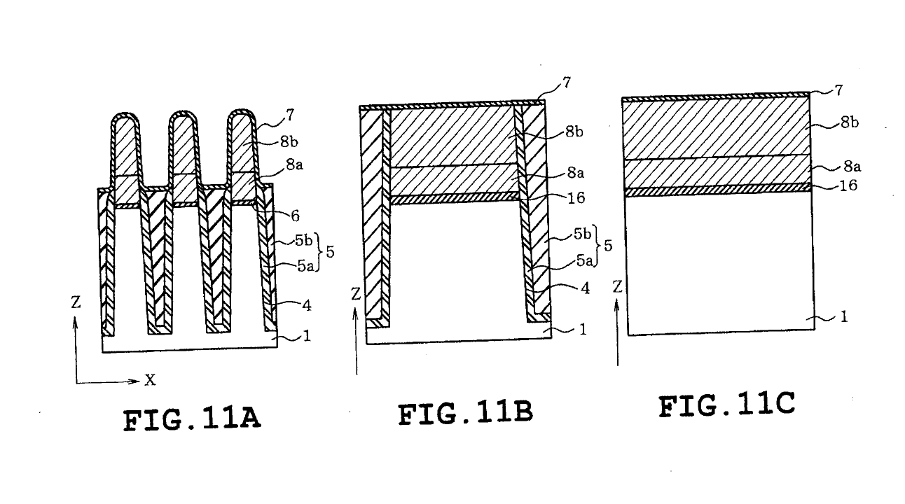

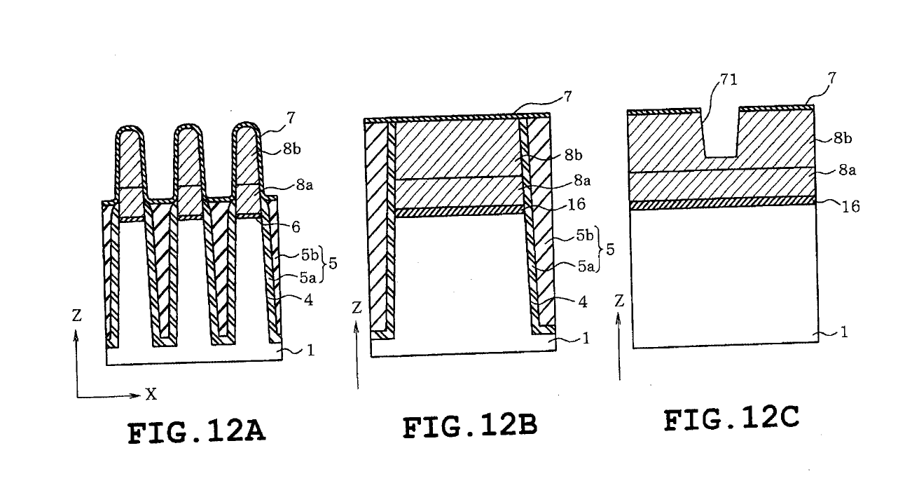

Then, as shown in FIGS. 11A to 11C, interelectrode insulating film 7 made of for example a NONO film is formed for example by CVD. As a result, interelectrode insulating film 7 is formed so as to continuously cover the upper surface of element isolation insulating film 5, the side surfaces of lower polysilicon film 8a, and the side surfaces and the upper surface of upper polysilicon film 8b. Thus, the boundary of upper polysilicon film 8b is surrounded by nitrogen in the X direction. At this moment, upper polysilicon film 8b is not divided in the Y direction. Then, as shown in FIGS. 12A to 12C, interelectrode insulating film 7 is coated by resist (not shown) which is patterned and used as a mask for processing interelectrode insulating film 7 and upper polysilicon film 8b in peripheral-circuit region P by for example RIE to form opening 71.

Next, as shown in FIGS. 5A to 5C, the resist pattern is removed and polysilicon film 9 doped with boron or the like is further formed above interelectrode insulating film 7 and in opening 71 by for example CVD. Then, cap film 26 made of a silicon nitride film is formed above polysilicon film 9. Further, in memory-cell region M, polysilicon film 9, interelectrode insulating film 7, upper polysilicon film 8b, and lower polysilicon film 8a are divided in the Y direction (in the direction normal to the page) as viewed in FIG. 5A. Then, liner film 27 made of a silicon oxide film, silicon nitride film 28 serving as a stopper film, and interlayer insulating film 29 are formed one after another. Subsequent process steps will not be described.

In the present embodiment having the above described structure, floating electrode FG of memory-cell-transistor MT is formed by stacking lower polysilicon film 8a doped with a high concentration of nitrogen and upper polysilicon film 8b doped for example with a high concentration of boron. Further, height h1 of the upper end portion of lower polysilicon film 8a is made higher than height h2 of the upper surface of element isolation insulating film 5. Thus, in the cross section taken in along the X direction, it is possible to cover the under surface, the side surfaces, and the upper surface of upper polysilicon film 8b doped with high concentration of boron with lower polysilicon film 8a doped with high concentration of nitrogen and the nitride film of interelectrode insulating film 7. As a result, upper polysilicon film 8b is surrounded by nitrogen as viewed in the cross section taken along the X direction and thus, it is possible to inhibit external diffusion of boron introduced into upper polysilicon film 8b as a dopant by a thermal process, or the like, carried out during memory cell processing. Thus, it is possible to inhibit depletion near the interface where floating electrode FG contacts interelectrode insulating film 7 and thereby inhibit programming errors and stabilize programming/erasing properties.

Further, in the present embodiment, nitrogen is doped in lower polysilicon film 8a disposed in peripheral-circuit region P so as to reduce the grain diameter of polysilicon of lower polysilicon film 8a. As a result, it is possible to inhibit permeation of hydrofluoric acid into lower polysilicon film 8a during the wet etching for forming opening 71 in interelectrode insulating film 7 and upper poly silicon film 8b. As result, it is possible to prevent degradation of gate insulating film 16.

Further, in the present embodiment, polysilicon films 8a and 8b serving as floating electrode FG of memory-cell region M and polysilicon films 8a and 8b serving as a part of a gate electrode of transistor Tp of peripheral-circuit region P are formed in a similar structure with a similar process step. As a result, it is possible to prevent external diffusion of boron (B) with small number of process steps and improve the P-type impurity concentration in polysilicon film 8 disposed in memory-cell region M. It is further possible to inhibit permeation of hydrofluoric acid into lower polysilicon film 8a during the wet etching for forming opening 71 in interelectrode insulating film 7 and upper polysilicon film 8b disposed in peripheral-circuit region P.

A small amount of boron may diffuse from upper polysilicon film 8b to lower polysilicon film 8a. However, it is possible to obtain the effects of the present invention if boron concentration is reduced from the boundary between upper polysilicon film 8b and lower polysilicon film 8a. Further, it is possible to identify the boundary between lower polysilicon film 8a and upper polysilicon film 8b by the grain size of polysilicon.

### Second Embodiment

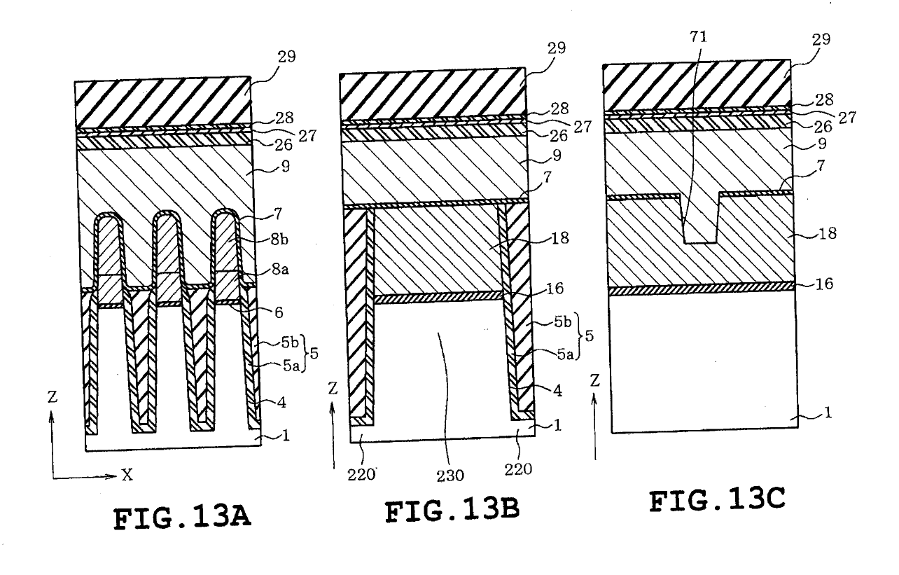

FIGS. 13 to 18 illustrate a second embodiment. Elements that are identical to the first embodiment are identified with identical reference symbols. In the second embodiment, polysilicon film (corresponding to polysilicon films 8a and 8b of the first embodiment) of memory-cell region M and peripheral-circuit region P are formed in different process steps and in different structures.

The plan view and the structure of memory-cell region M are similar to those of the first embodiment and thus, are not re-described.

FIG. 13B schematically illustrates the cross section (cross section taken along line B-B of FIG. 4) of a main portion of peripheral-circuit region P. FIG. 13C schematically illustrates the cross section (cross section taken along line C-C of FIG. 4) of a main portion of peripheral-circuit region P.

As shown in FIGS. 13B and C, gate insulating film 16, having a thickness thicker than the thickness of gate insulating film 6, is formed above element region 230, and polysilicon film 18 is stacked above gate insulating film 16. Polysilicon film 18 is formed in a different process step and by a different film forming material from those of lower polysilicon film 8a and upper polysilicon film 8b constituting the aforementioned floating electrode FG. Upper polysilicon film 18 may be an N type polysilicon film 18 doped with impurities such as phosphorous or arsenic. The thickness of polysilicon film 18 is specified so as to be substantially the same as the thickness of polysilicon films 8a and 8b of memory-cell region M. The thickness of polysilicon film 18 may be specified so as to be thicker or thinner than the thickness of polysilicon films 8a and 8b of memory-cell region M.

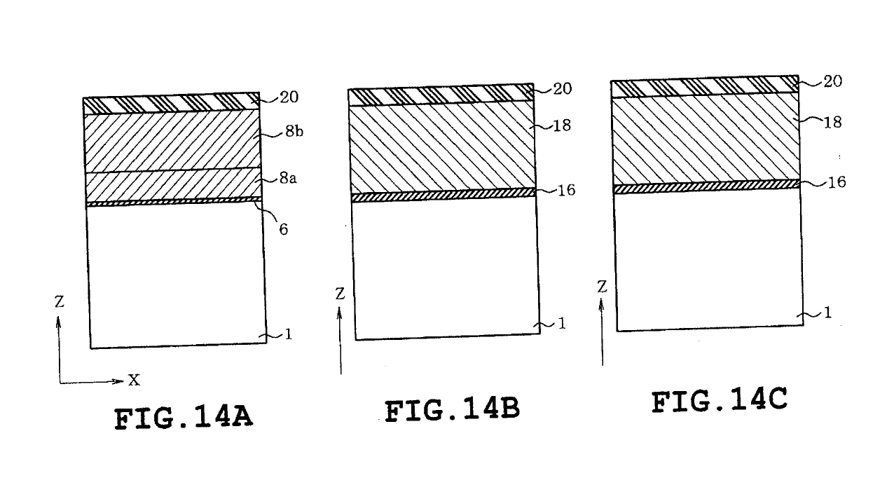

Next, description will be given on the manufacturing process flow in a step by step manner with reference to FIGS. 14 to 18. The process steps are described below focusing on their features and known steps may be added. FIGS. 14A to 18A are cross sectional views taken along line A-A of FIG. 3 and schematically illustrate the manufacturing process flow of the structures in memory-cell region M. FIGS. 14B to 18B are cross sectional views taken along line B-B of FIG. 4 and schematically illustrate the manufacturing process flow of the structures in memory cell peripheral-circuit region P. FIGS. 14C to 14C are cross sectional views taken along line C-C of FIG. 4 and schematically illustrate the manufacturing process flow of the structures in memory cell peripheral-circuit region F.

As shown in FIG. 14A, polysilicon films 8a and 8b serving as floating electrode FG of memory-cell region M is formed in a similar manner as in the first embodiment. Then, as shown in FIGS. 14B and C, polysilicon film 18 serving as apart of the gate electrode of transistor Tp disposed in peripheral-circuit region P is formed in a different process step. Polysilicon film 18 may be an N type polysilicon film 18 doped with impurities such as phosphorous or arsenic and formed for example by CVD. The thickness of polysilicon film 18 is specified so as to be substantially the same as the thickness of polysilicon films 8a and 8b of memory-cell region M. The thickness of polysilicon film 18 may be specified so as to be thicker or thinner than the thickness of polysilicon films 8a and 8b of memory-cell region M.

Then, as shown in FIGS. 14A to 14C, hard mask 20 formed of for example a silicon nitride film or a silicon oxide film, or the like, are formed above upper polysilicon film 8b and polysilicon film 18.

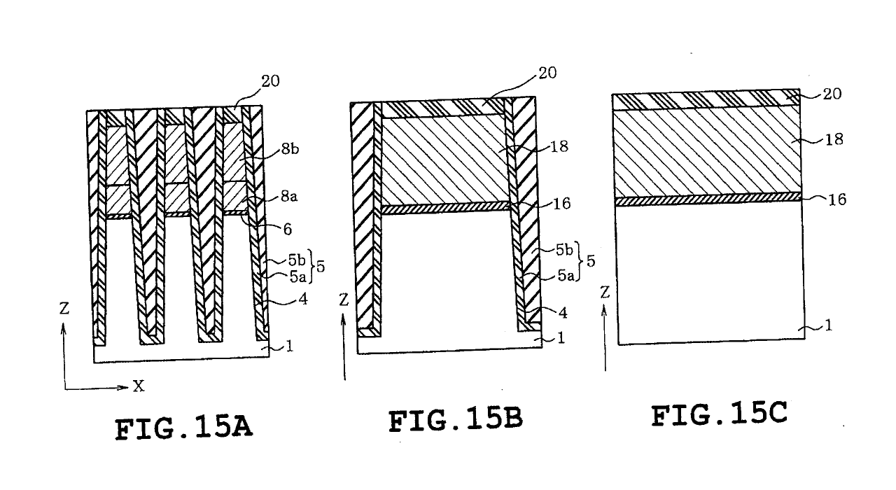

Then, resist 22 is coated above hard mask 20 and resist 22 is patterned by lithography. Thereafter, using the patterned resist 22 as mask, element isolation trench 4 is formed by processing hard mask 20, polysilicon films 8b and 8a, polysilicon film 18, gate insulating films 6 and 16, and the upper portion of semiconductor substrate 1 one after another by for example RIE (see FIGS. 7A to 7C and FIGS. 8A to 8C). Subsequently, liner oxide film 5a is formed along the inner surface of element isolation trench 4, whereafter a coating-type silicon oxide film 5b is formed above liner oxide film 5a to form a double layered element isolation insulating film 5. Then, element isolation insulating film 5 is planarized by CMP for example using hard mask 20 as a stopper. As a result, the structures illustrated in FIGS. 15A to 150 are obtained.

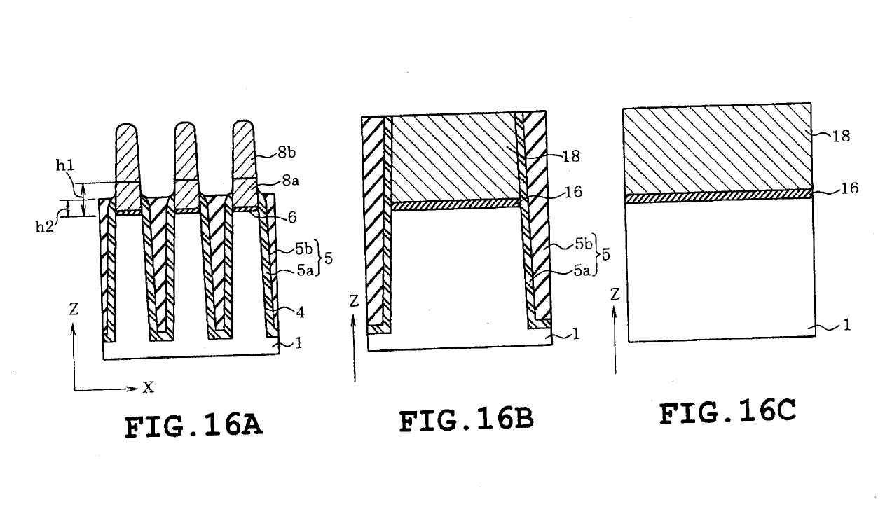

Then, as shown in FIGS. 16A to 16C, the upper portion of element isolation insulating film 5 in memory-cell region M is etched for example by RIE so that height h1 of the upper end portion of lower polysilicon film 8a is higher than the height h2 of the upper surface of element isolation insulating film 5 (see FIG. 16A). Thereafter, hard mask 20 is removed for example by hot phosphoric acid treatment.

The upper surface of element isolation insulating film 5 is not etched in peripheral-circuit region P. As a result, the upper surface of element isolation insulating film 5 and the upper surface of upper polysilicon film 8b are substantially level in peripheral-circuit region P.

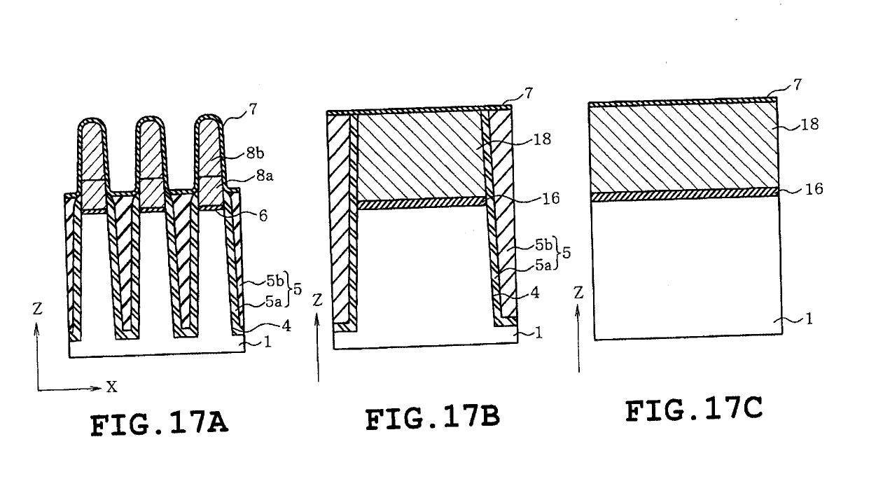

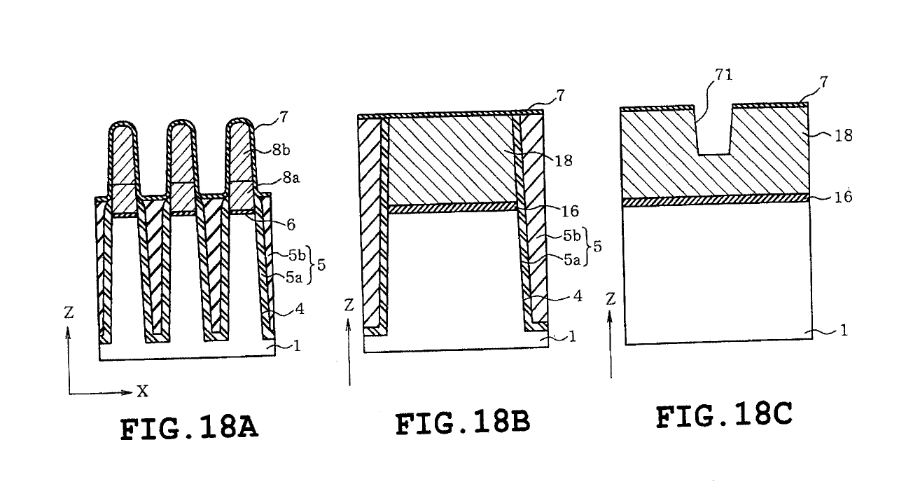

Then, as shown in FIGS. 17A to 17C, interelectrode insulating film 7 made of for example a NONO film is formed for example by CVD. Thereafter, as shown in FIGS. 18A to 18C, interelectrode insulating film 7 is coated by resist (not shown) which is patterned and used as a mask for processing interelectrode insulating film 7 and polysilicon film 18 in peripheral-circuit region P by for example RIE to form opening 71.

Next, as shown in FIGS. 13A to 13C, the resist pattern is removed and polysilicon film 9 doped with boron or the like is further formed above interelectrode insulating film 7 and in opening 71 by for example CVD. Then, cap film 26 made of a silicon nitride film is formed above polysilicon film 9. Further, in memory-cell region M, polysilicon film 9, interelectrode insulating film 7 upper polysilicon film 8b, and lower polysilicon film 8a are divided in the Y direction (in the direction normal to the page) as viewed in FIG. 5A. Then, liner film 27 made of a silicon oxide film, silicon nitride film 28 serving as a stopper film, and interlayer insulating film 29 are formed one after another. Subsequent process steps will not be described.

The structures of the second embodiment other than those described above are identical to the structures of the first embodiment. Thus, the second embodiment also achieves operation and effect similar to those of the first embodiment. Especially in the second embodiment, polysilicon film 18 serving as a part of the gate electrode of transistor Tp in peripheral-circuit region P, is formed in a different process step from polysilicon films 8a and 8b constituting the aforementioned floating electrode FG of memory-cell region M. Thus, it is possible to adjust the electrical properties of transistor Tp in peripheral-circuit region P without relying on the properties of memory-cell transistor MT.

### Third Embodiment

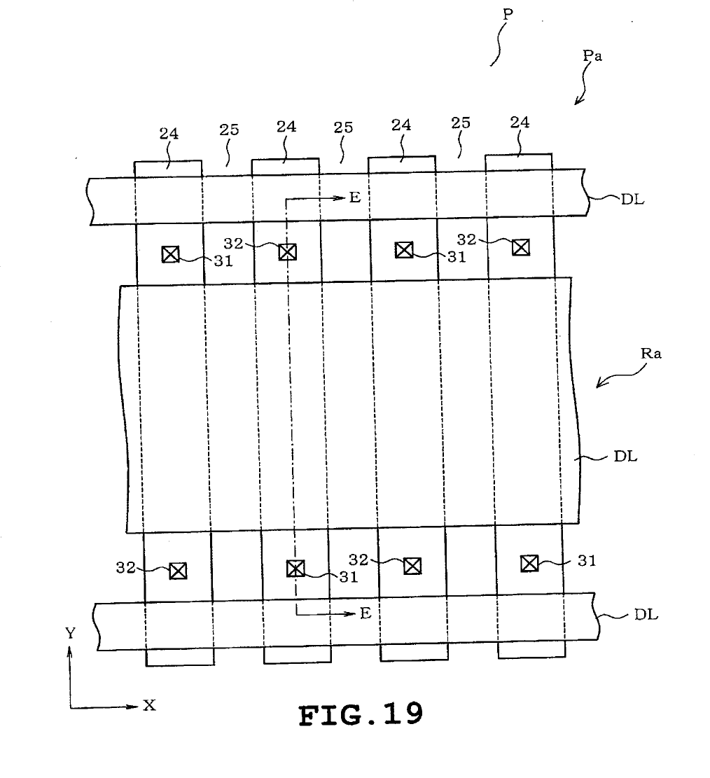

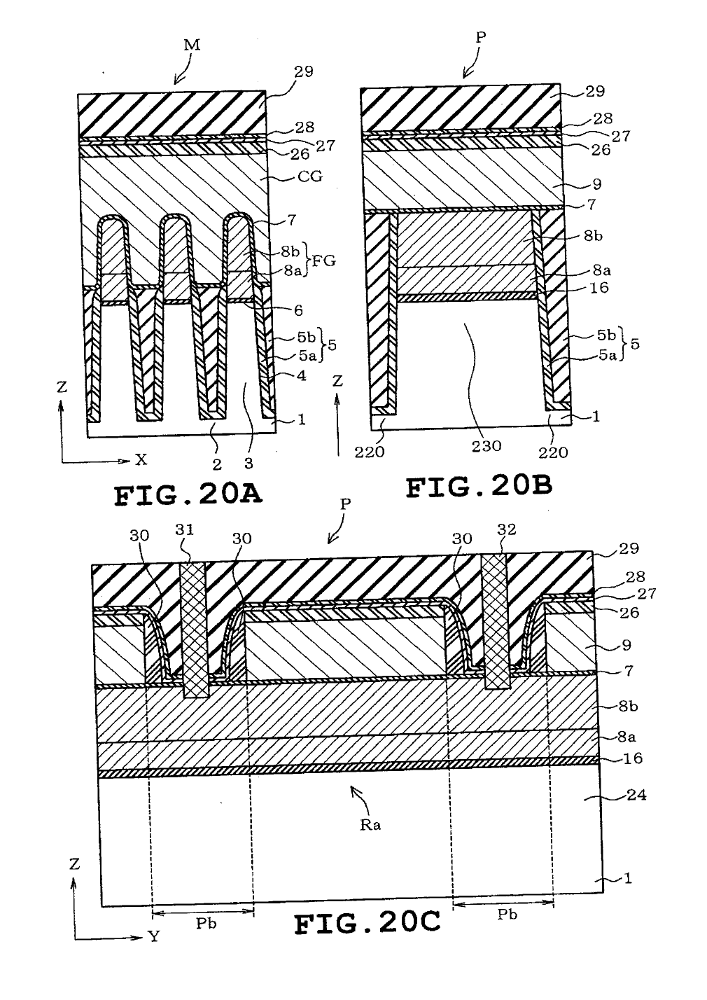

FIGS. 19 to 20 illustrates second embodiment. Elements that are identical to the first embodiment are identified with identical reference symbols. In the third embodiment, resistive element Ra is formed in peripheral-circuit region P. Various circuits such as a logic circuit, a booster circuit, or the like are provided in peripheral-circuit region P and resistive element Ra is a component of such circuits.

FIG. 19 is a plan view of region Pa for forming resistive element Ra in peripheral-circuit region P. As shown in FIG. 19, element regions 24 extend in the Y direction and are disposed at a predetermined spacing along the X direction. These element regions 24 are electrically isolated by element isolation region 25. Dummy lines DL are formed so as to extend in the X direction and cross with element regions 24 and element isolation regions 25. Dummy line DL is substantially identical in structure as control electrode CG described in the first embodiment. Between dummy lines DL, via plugs 31 and 32 are formed which connect element regions 24 and their overlying connection layers (not shown). Dummy line DL is formed of upper polysilicon film 8b and lower polysilicon film 8a.

FIG. 20C illustrate a schematic cross section (cross section taken along line E-E of FIG. 19) of resistor element Ra. FIGS. 20A and 20B respectively correspond to the schematic cross section (cross section taken along line A-A of FIG. 3) of memory-cell MT in memory-cell region M and the schematic cross section (cross section taken along line B-B of FIG. 4) of transistor Tp in peripheral-circuit region P described in the first embodiment.

In the region for forming resistor element Ra, gate insulating film 16 is formed above element region 24 and lower polysilicon film 8a, upper polysilicon film 8b, interelectrode insulating film 7, polysilicon film 9, and cap film 26 are formed one after another above gate insulating film 16 as shown in FIG. 20C.

Among them, polysilicon film 9 and cap film 26 are divided in the cross section of FIG. 20C. In divided region Pb, spacer film 30 is formed along both sides of polysilicon film 9 and cap film 26. Further, liner film 27 and silicon nitride film 28 are formed along the upper surfaces and upper side surfaces of cap film 26 and spacer film 30 as well as along the upper surface of interelectrode insulating film 7 disposed in divided region Pb. Interlayer insulating film 29 is formed above liner film 27 and silicon nitride film 28.

Further in divided region Ph, via plug 31 and 32 are formed so as to extend through interlayer insulating film 29, liner film 27, and silicon nitride film 28 and into upper polysilicon film 8b to contact upper polysilicon film 8b. Above gate insulating film 16 in divided region Pb, a double layered polysilicon film (lower polysilicon film 8a and upper polysilicon film 8b) are stacked one over the other so as to be located in the same layer with floating electrode FG (see the first embodiment). Polysilicon films 8a and 8b between each via plug 31 and 32 serve as the primary resistor of resistive element Ra. Lower polysilicon film 8a is doped for example with nitrogen. Upper polysilicon film 8b is doped for example with boron.

The under surfaces of via plug 31 and 32 may be located in upper polysilicon film 8b or in lower polysilicon film 8a.

The structures of the third embodiment other than those described above are identical to the structures of the first embodiment. Thus, it is also possible for the third embodiment to achieve operation and effect similar to those of the first embodiment. In particular, in the third embodiment, it is possible to form resistive element Ra in peripheral-circuit region P in which polysilicon films 8a and 8b between via plug 31 and 32 serve as a resistor.

Further, it is possible to form polysilicon films 8a and 8b, serving as the resistor of the resistive element, and memory-cell transistor MT at the same time. As a result, it is possible to simplify the manufacturing process flow.

### Fourth Embodiment

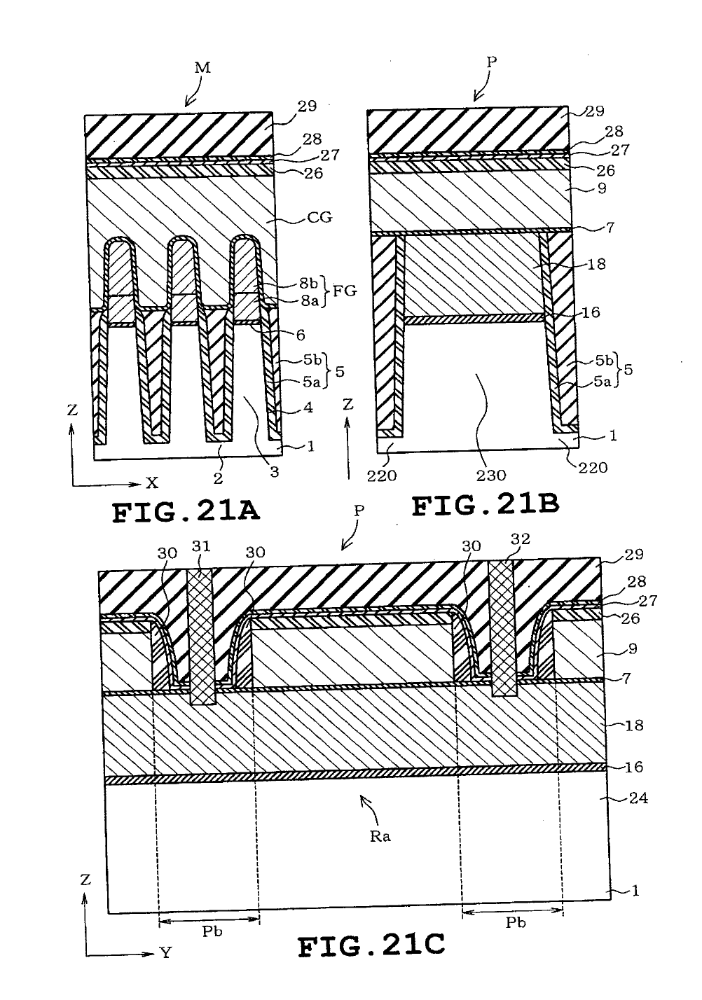

FIG. 21 illustrates a fourth embodiment. Elements that are identical to the second and the third embodiment are identified with identical reference symbols. In the fourth embodiment, the polysilicon film serving as the resistor of the resistor element is formed in a different process step and in a different structure from those of polysilicon film 8 and 8b of memory cell transistor MT as was the case in the second embodiment.

More specifically, as shown in FIG. 21A, polysilicon films 8a and 8b serving as floating electrode FG of memory-cell region M are formed in a similar manner as in the first embodiment. Then, as shown in FIGS. 21B and C, polysilicon film 18 serving as a part of the gate electrode of transistor Tp disposed in peripheral-circuit region P is formed in a different process step. Polysilicon film 18 may be an N type polysilicon film 18 doped with impurities such as phosphorous or arsenic and formed for example by CVD. The thickness of polysilicon film 18 is specified so as to be substantially the same as the thickness of polysilicon films 8a and 8b of memory-cell region M. The thickness of polysilicon film 18 may be specified so as to be thicker or thinner than the thickness of polysilicon films 8a and 8b of memory-cell region M.

The structures of the fourth embodiment other than those described above are identical to the structures of the second and third embodiment. Thus, it is also possible for the fourth embodiment to achieve operation and effect similar to those of the second and third embodiment. In particular, in the fourth embodiment, it is possible to form resistive element Ra in peripheral-circuit region P in which polysilicon film 18 between via plug 31 and 32 serve as resistor. Further, it is possible to readily control the resistance of resistive element Ra through adjustment of film properties of polysilicon film 18 (such as the types of impurities and their dose).

### Fifth Embodiment

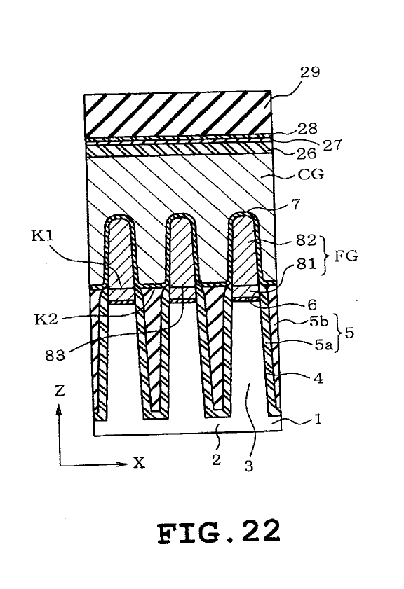

FIGS. 22 to 27 illustrate a fifth embodiment. Elements identical to those of the first embodiment are identified with identical reference symbols. The fifth embodiment differs from the first embodiment in the film structure of floating gate electrode FG of memory-cell region as well as the material and the manufacturing process flow of floating gate electrode. The structures as viewed in the plan view and the structures of peripheral circuit region P are identical to those of the first embodiment and thus, will not be described.

FIG. 22 schematically illustrates the cross section of the main portions of memory-cell region M (the cross section taken along line A-A of FIG. 3). As illustrated in FIG. 22, element isolation trenches 4 are formed into semiconductor substrate 1 and element isolation trenches 4 are filled with element isolation film 5 to form element isolation regions 2 taking an STI (Shallow Trench Isolation) structure. Element isolation insulating film 5 is a double layer insulating film comprising liner oxide film 5a and silicon oxide film 5b. Element regions 3 are provided between adjacent element isolation regions 2. Each of memory-cell transistors MT are formed above element region 3. Each memory-cell transistor MT comprises a stack of gate insulating film 6, floating electrode FG, interelectrode insulating film 7, and control electrode CG.

Floating electrode FG comprises a stack of lower polysilicon film 81 and upper polysilicon film 82. Lower polysilicon film 81 is a P-type polysilicon doped with N-type impurities such as phosphorous (P) and P-type impurities such as boron (B). The impurity concentration of lower polysilicon film 81 is configured so that concentration of P-type impurities is greater than the concentration of N-type impurities. Thus, the conductivity type of lower polysilicon film 81 exhibits a P type (P type in net dose). Upper polysilicon film 82 includes P-type impurities (such as boron (B)) and N-type impurities (phosphorous (P)) diffused by heat from lower polysilicon film 81. The impurity concentration of upper polysilicon film 82 is configured so that concentration of P-type impurities is greater than the concentration of N-type impurities. Thus, the conductivity type of upper polysilicon film 82 exhibits a P type (P type in net dose).

The side surface and the upper surface of upper polysilicon film 82 are covered by interelectrode insulating film 7. The side surface of lower polysilicon film 81 is covered by element isolation insulating film 5. Height K1 of the upper surface of lower polysilicon film 81 (i.e. the location of the boundary of lower polysilicon film 81 and upper polysilicon film 82) is substantially level with height K2 of the lower surface of the portion of interelectrode insulating film 7 closest to silicon substrate 1 (the lowest portion). Height K1 may be configured to be lower than height K2.

Further, the size of crystal grain diameter of lower polysilicon film 81 is configured to differ from the size of crystal grain diameter of upper polysilicon film 82. Thus, grain boundary (dividing layer) 83 may be formed between lower polysilicon film 81 and upper polysilicon film 82.

The film structures of interelectrode insulating film 7 and control electrode CG are substantially identical to those of the first embodiment. Above control electrode CG, cap film 26, liner film 27, silicon nitride film 28, and interlayer insulating film 29 are formed which are substantially identical to the structures of the first embodiment.

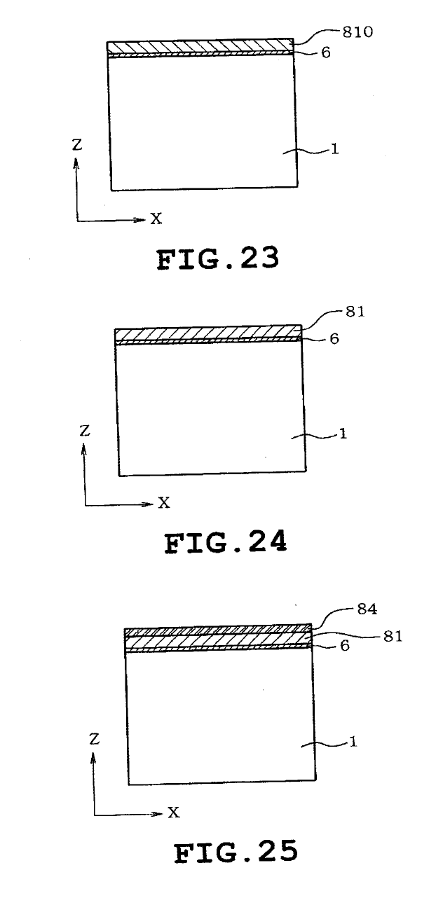

Next, the process steps of the manufacturing process flow of the above described structure will be described one by one with reference to FIGS. 23 to 27. The description will focus on the features of the process steps and thus, commonly known process steps may be added as required. FIGS. 23 to 27 are cross sectional views taken along line A-A of FIG. 3 and each schematically illustrate one manufacturing phase of the structures in memory-cell region M.

First, as illustrated in FIG. 23, gate insulating film 6 is formed above semiconductor substrate 1 of memory-cell region M by thermal oxidation for example. Gate insulating film 6 is formed of a silicon oxide film for example and serves as a tunnel insulating film. Then, amorphous silicon film 810 doped with N-type impurities such as phosphorous (P) is formed above gate insulating film 6 by CVD for example. In the fifth embodiment, amorphous silicon film 810 is doped with approximately 3×10²⁰ cm⁻³ of phosphorous for example which approximates the solid solubility limit. This phosphorous concentration is referred to as concentration D1.

Then, as illustrated in FIG. 24, amorphous silicon film 810 is crystallized by crystallization anneal to form lower polysilicon film 81. Lower polysilicon film 81 is doped with phosphorus having a concentration approximating the solid solubility limit.

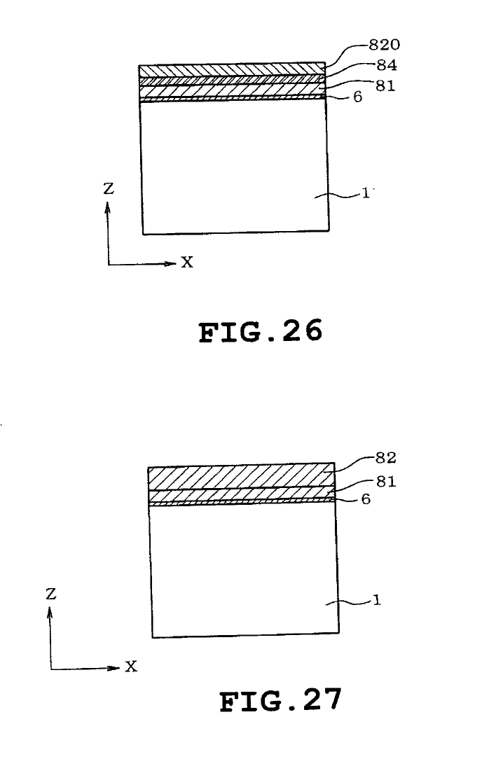

Then, as illustrated in FIG. 25, seed layer 84 formed of disilane for example is formed above lower polysilicon film 81. Then, as illustrated in FIG. 26, amorphous silicon film 820 doped with 2-type impurities such as boron (B) is formed for example by CVD above seed layer 84. Amorphous silicon film 820 is doped with approximately 3×10²⁰ cm⁻³ of boron. This boron concentration is referred to as concentration D2. The relation between concentration D1 and D2 preferably satisfy D2>D1.

Then, as illustrated in FIG. 27, amorphous silicon film 820 is crystallized by crystallization anneal to form upper polysilicon film 82. The crystallization anneal causes boron to diffuse from upper polysilicon film 82 to lower polysilicon film 81. However, lower polysilicon film 81 is pre-doped with phosphorous at a concentration approximating the solid solubility limit. Because very little amount of impurities are soluble into lower polysilicon film 81, it is difficult for boron to diffuse into lower polysilicon film 81. Thus, boron concentration in lower polysilicon film 81 results in a small amount. However, boron concentration in lower polysilicon film 81 is at a level to allow lower polysilicon film 81 to become a P-type polysilicon. That is, the impurity concentration of lower polysilicon film 81 is configured so that the concentration of P-type impurities is greater than the concentration of N-type impurities. Further, a grain boundary is formed between upper polysilicon film 82 and lower polysilicon film 81 as the result of this process step.

This is followed by process steps such as forming element isolation trenches 4; filling element isolation trenches 4 with element isolation insulating film 5; forming interelectrode insulating film 7; and forming control electrode CG, cap film 26, liner film 27, silicon nitride film 28, and interlayer insulating film 29 as was the case in the first embodiment.

In the above described fifth embodiment, floating electrode FG of the memory cell comprises a lower polysilicon film 81 containing phosphorous and an upper polysilicon film 82 containing boron. Further, lower polysilicon film 81 is configured as a P-type polysilicon. Thus, erase operation can be executed at low voltage levels since boron concentration in lower polysilicon film 81 of floating electrode FG stays low. As a result, it is possible to reduce the degradation of write/erase tolerance of the gate insulating film originating from electrical stress. Further, because the boron concentration of lower polysilicon film 81 of floating electrode FG stays low, it is possible to inhibit diffusion of boron into the gate insulating film and thereby improve the reliability of the memory cell.

Further, in the fifth embodiment, lower polysilicon film 81 is formed by: forming amorphous silicon film 810 doped with phosphorous at a concentration approximating the solid solubility limit above the gate insulating film 6; and crystallizing amorphous silicon film 810 by crystallization anneal. Then, upper polysilicon film 82 is formed by: forming seed layer 84 comprising disilane for example above lower polysilicon film 81; forming amorphous silicon film 820 doped with boron above seed layer 84; and crystallizing amorphous silicon film 820 by crystallization anneal. The crystallization anneal of amorphous silicon film 820 causes boron to diffuse from upper polysilicon film 82 to lower polysilicon film 81. However, lower polysilicon film 81 is pre-doped with phosphorous at a concentration approximating the solid solubility limit. Because very little amount of impurities are soluble into lower polysilicon film 81, it is difficult for boron to diffuse into lower polysilicon film 81. Thus, it is possible to control boron concentration in lower polysilicon film 81 to a small amount.

In the example discussed in the fifth embodiment, amorphous silicon film 810 is doped with approximately 3×10²⁰ cm⁻³ of phosphorous for example which approximates the solid solubility limit. However, concentration of phosphorous may range approximately from 1×10²⁰ cm⁻³ to 3×10²⁰ cm⁻³ for example.

### Other Embodiments

The following structure may be adopted in addition to the foregoing embodiments.

In each of the foregoing embodiments, carbon (C) may be introduced in lower polysilicon film 8a and upper polysilicon film 8b that constitute floating electrode FG of memory-cell region M. Because carbon (C) is introduced into polysilicon films 8a and 8b, it is possible to increase crystal defects near the interface where floating electrode FG contacts interelectrode insulating film 7. As a result, it is possible to reduce the size of grain diameters of polysilicon films 8a and 8b as much as possible and inhibit depletion as much as possible.

Further, phosphorous doped as N-type impurities in lower polysilicon film 81 of floating electrode FG of memory-cell region M in the fifth embodiment may be replaced by arsenic (As). Further, lower polysilicon film 81 and upper polysilicon film 82 forming floating electrode FIG may each be doped carbon (C) or nitrogen (N).

As described above, in the semiconductor device according to the embodiments, it is possible to inhibit diffusion of boron introduced into upper polysilicon film 8b as a dopant by a thermal process, or the like, carried out during memory cell processing. Thus, it is possible to inhibit depletion near the interface where floating electrode FG contacts interelectrode insulating film 7 as much as possible and thereby inhibit programming errors and stabilize the programming/erasing properties.

While certain embodiments have been described, these embodiments have been presented by way of example only, and are not intended to limit the scope of the inventions. In particular, nitrogen is introduced in lower polysilicon film 8a in order to prevent external diffusion of boron. However, nitrogen may be replaced by any material that is capable of preventing external diffusion of boron. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a memory cell region including a memory cell in which a floating electrode is disposed above a gate insulating film and a control electrode is stacked above the floating electrode via an interelectrode insulating film,
wherein the floating electrode of the memory cell includes a first polysilicon layer containing nitrogen and a second polysilicon layer containing a P-type impurity, and
wherein a height of an upper surface of an end of the first polysilicon layer is higher than a height of an upper surface of an element isolation insulating film disposed in the memory cell region.

2. The device according to claim 1, further comprising a peripheral-circuit region provided in a periphery of the memory-cell region and a peripheral element disposed in the peripheral circuit region, the peripheral element including a third polysilicon layer disposed above an insulating film and comprising a stack of the first polysilicon layer and the second polysilicon layer and an electrode disposed above the third polysilicon layer via an insulating film including the same material as the interelectrode insulating film.

3. The device according to claim 2, wherein the interelectrode insulating film includes an opening connecting the second polysilicon layer and the control electrode, and wherein an under surface of the electrode is higher than an upper surface of the first polysilicon layer.

4. The device according to claim 1, further comprising a peripheral-circuit region provided in a periphery of the memory-cell region and a second peripheral element disposed in the peripheral circuit region, the second peripheral element including a fourth polysilicon layer free of nitrogen disposed above an insulating film and an electrode disposed above the fourth polysilicon layer via an insulating film including the same material as the interelectrode insulating film.

5. The device according to claim 4, wherein a thickness of the fourth polysilicon layer equals a sum of a thickness of the first polysilicon layer and a thickness of the second polysilicon layer.

6. The device according to claim 4, wherein the fourth polysilicon layer contains an N-type impurity.

7. The device according to claim 2, wherein the peripheral-circuit region includes a resistive element, the resistive element including a third polysilicon layer disposed above the insulating film and comprising a stack of the first polysilicon layer and the second polysilicon layer and an insulating film including the same material as the interelectrode insulating film disposed above the third polysilicon layer.

8. The device according to claim 4, wherein the peripheral-circuit region includes a resistive element, the resistive element comprising a stack of a fourth polysilicon layer free of nitrogen and having a thickness equal to a sum of a thickness of the first polysilicon layer and a thickness of the second polysilicon layer and an insulating film including the same material as the interelectrode insulating film.

9. A semiconductor device comprising:
a memory cell region including a memory cell in which a floating electrode is disposed above a gate insulating film and a control electrode is stacked above the floating electrode via an interelectrode insulating film,
wherein the floating electrode includes a fifth polysilicon layer having a small polysilicon grain-diameter and a second polysilicon layer containing a P-type impurity, and
wherein a height of an upper surface of an end of the fifth polysilicon layer is higher than a height of an upper surface of an element isolation insulating film disposed in the memory cell region.

10. The device according to claim 9, further comprising a peripheral-circuit region provided in a periphery of the memory-cell region and a peripheral element disposed in the peripheral circuit region, the peripheral element including a stack of the fifth polysilicon layer and the second polysilicon layer disposed above an insulating film and an electrode disposed above the second polysilicon layer via an insulating film including the same material as the interelectrode insulating film.

11. The device according to claim 10, wherein the interelectrode insulating film includes an opening connecting the second polysilicon layer and the electrode, and wherein an under surface of the electrode is higher than an upper surface of the fifth polysilicon layer.

12. The device according to claim 10, further comprising a peripheral-circuit region provided in a periphery of the memory-cell region and a second peripheral element disposed in the peripheral circuit region, the second peripheral element including a fourth polysilicon layer free of nitrogen disposed above an insulating film and an electrode disposed above the fourth polysilicon layer via an insulating film including the same material as the interelectrode insulating film.

13. The device according to claim 12, wherein a thickness of the fourth polysilicon layer equals a sum of a thickness of the fifth polysilicon layer and a thickness of the second polysilicon layer.

14. The device according to claim 12, wherein the fourth polysilicon layer contains an N-type impurity.

15. The device according to claim 10, wherein the peripheral-circuit region includes a resistive element, the resistive element including a sixth polysilicon layer disposed above the insulating film and comprising a stack of the fifth polysilicon layer and the second polysilicon layer and an insulating film including the same material as the interelectrode insulating film disposed above the sixth polysilicon layer.

16. The device according to claim 10, wherein the peripheral-circuit region includes a resistive element, the resistive element comprising a stack of a fourth polysilicon layer free of nitrogen and having a thickness equal to a sum of a thickness of the fifth polysilicon layer and a thickness of the second polysilicon layer and an insulating film including the same material as the interelectrode insulating film.

17. A semiconductor device comprising:
a memory cell region including a memory cell in which a floating electrode is disposed above a gate insulating film and a control electrode is stacked above the floating electrode via an interelectrode insulating film,
wherein the floating electrode of the memory cell includes a lower polysilicon layer having a P-type impurity and an N-type impurity, and an upper polysilicon layer having a P-type impurity and an N-type impurity, and
wherein conductivity types of both the upper polysilicon layer and the lower polysilicon layer are substantially P-type.

18. The device according to claim 17, wherein the lower polysilicon layer has an N-type impurity concentration approximating a solid solubility limit.

19. The device according to claim 17, wherein a location of a boundary surface of the lower polysilicon layer and the upper polysilicon layer are configured to be level with an under surface of a lowest portion of the interelectrode insulating film.

20. The device according to claim 17, wherein a size of a crystal grain diameter of the lower polysilicon layer and a size of a crystal grain diameter of the upper polycrystalline layer are different.

21. The device according to claim 17, wherein a grain boundary exist between the lower polysilicon layer and the upper polycrystalline layer.
